(19) United States
(12) Patent Application Publication
(10) Pub. No.: US 2014/0166094 A1
(43) Pub. Date: Jun. 19, 2014

(54) SOLAR CELL EMITTER REGION FABRICATION USING ETCH RESISTANT FILM

(71) Applicants: Paul Loscutoff, Castro Valley, CA (US); Peter J. Cousins, Menlo Park, CA (US)

(72) Inventors: Paul Loscutoff, Castro Valley, CA (US); Peter J. Cousins, Menlo Park, CA (US)

(21) Appl. No.: 13/718,518

(22) Filed: Dec. 18, 2012

(51) Int. Cl. H01L 31/0236; H01L 31/18

(52) U.S. Cl. CPC H01L 31/02366; H01L 31/18
USPC 136/256; 438/71

(57) ABSTRACT

Methods of fabricating solar cell emitter regions using etch resistant films and the resulting solar cells are described. In an example, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. A capping layer is formed on the P-type dopant-containing layer. An etch resistant layer is formed on the capping layer. A second surface of the substrate, opposite the first surface, is etched to texturize the second surface of the substrate. The etch resistant layer protects the capping layer and the P-type dopant-containing layer during the etching.

### TECHNICAL FIELD

Embodiments of the present invention are in the field of renewable energy and, in particular, methods of fabricating solar cell emitter regions using etch resistant films and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present invention allow for increased solar cell manufacture efficiency by providing novel processes for fabricating solar cell structures. Some embodiments of the present invention allow for increased solar cell efficiency by providing novel solar cell structures.

### BRIEF DESCRIPTION OF THE DRAWINGS

FIGS. 1A-1G illustrate cross-sectional views of various stages in the fabrication of a solar cell, in accordance with an embodiment of the present invention.

FIGS. 2A and 2B illustrate cross-sectional views of various stages in the fabrication of a solar cell.

FIGS. 3A-3E illustrate cross-sectional views of various stages in the fabrication of a solar cell, in accordance with an embodiment of the present invention.

FIGS. 4A-4D illustrate cross-sectional views of various stages in the fabrication of a solar cell.

FIGS. 5A-5E illustrate cross-sectional views of various stages in the fabrication of a solar cell, in accordance with an embodiment of the present invention.

### DETAILED DESCRIPTION

Methods of fabricating solar cell emitter regions using etch resistant films and the resulting solar cells are described herein. In the following description, numerous specific details are set forth, such as specific process flow operations, in order to provide a thorough understanding of embodiments of the present invention. It will be apparent to one skilled in the art that embodiments of the present invention may be practiced without these specific details. In other instances, well-known fabrication techniques, such as lithography and patterning techniques, are not described in detail in order to not unnecessarily obscure embodiments of the present invention. Furthermore, it is to be understood that the various embodiments shown in the figures are illustrative representations and are not necessarily drawn to scale.

Disclosed herein are methods of fabricating solar cells. In one embodiment, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. A capping layer is formed on the P-type dopant-containing layer. An etch resistant layer is formed on the capping layer. A second surface of the substrate, opposite the first surface, is etched to texturize the second surface of the substrate. The etch resistant layer protects the capping layer and the P-type dopant-containing layer during the etching. In another embodiment, a method of fabricating an emitter region of a solar cell includes forming a plurality of regions of an N-type dopant source film on a first surface of a substrate of the solar cell. A P-type dopant-containing layer is formed on the plurality of regions of the N-type dopant source film and on the first surface of the substrate between the regions of the N-type dopant source film. An etch resistant layer is formed on the P-type dopant-containing layer. A second surface of the substrate, opposite the first surface, is etched to texturize the second surface of the substrate. The etch resistant layer protects the P-type dopant-containing layer during the etching.

Also disclosed herein are solar cells. In one embodiment, an emitter region of a solar cell includes a plurality of regions of N-type doped silicon nano-particles disposed on a first surface of a substrate of the solar cell. Corresponding N-type diffusion regions are disposed in the substrate. A P-type dopant-containing layer is disposed on the plurality of regions of N-type doped silicon nano-particles and on the first surface of the substrate between the regions of N-type doped silicon nano-particles. Corresponding P-type diffusion regions are disposed in the substrate, between the N-type diffusion regions. A capping layer is disposed on the P-type dopant-containing layer. An etch resistant layer is disposed on the capping layer. A first set of metal contacts is disposed through the etch resistant layer, the capping layer, the P-type dopant-containing layer and the plurality of regions of N-type doped silicon nano-particles, and to the N-type diffusion regions. A second set of metal contacts is disposed through the etch resistant layer, the capping layer and the P-type dopant-containing layer, and to the P-type diffusion regions.

In a first aspect, one or more specific embodiments are directed to providing a bottom anti-reflective coating (bARC) deposition of silicon nitride (SiNx) or a moisture barrier, or both, before a random texturing (rantex) operation. In such an approach, the SiNx layer can be used as an etch-resist during the rantex etch. Generally, in developing a screen-printable dopant for bulk substrate solar cell fabrication, one technical issues involves having a dopant source material survive a rantex etch intact, so that it will be present for a subsequent dopant drive diffusion operation. Earlier attempts have included using a thick silicon glass oxide layer to prevent etching and moving the texture etch to a single-sided etch following a damage etch. Other approaches for etch resistance in dopant sources have included reformulating the material to add etch resistance, densifying the film prior to deposition of the P-type dopant containing layer or cap, and the use of single-sided texturizing techniques. These approaches, however, take time to develop and some require new tools, rendering them non-ideal for retrofitting into existing fabs.

More specifically, one or more embodiments in the second aspect address a need for increasing rantex resistance for dopant film stacks. In a particular embodiment, a plasma-enhanced chemical vapor deposited (PECVD) SiNₓ is used since the layer has a low (undetectable) etch rate in, e.g., KOH. Furthermore, since PECVD SiNₓ can be used as a bARC layer in bulk substrate based solar cell, existing toolsets and architectures can be maintained while increasing the etch resistance of the film stack by moving the bARC deposition after deposition of the P-type dopant containing layer of cap layer and before rantex. The resulting improved etch resistance may be particularly important for dopant material film stack that readily etches in KOH. Furthermore, the SiNₓ layer can provide an added advantage of defect fill-in for formed underlying layers, where present defects are covered and sealed by the SiNₓ layer.

Although, for example, an undoped silicate glass (USG) layer has a lower etch rate than Si, close to 2000 Angstroms of USG are typically etched in the rantex process. With SiNₓ on top of the film stack, the thickness (and therefore operating cost) of the USG layer can be reduced. The inclusion of an SiNx layer can add a degree of robustness to a standard film stack as well. Modifications of the current processing to allow for operation reduction can, in an embodiment, further include deposition of a doped layer (e.g., BSG or PSG) by PECVD. Another option is to use doped SiNₓ:B or SiNₓ:P layers as dopant sources for diffusion. These layers can be formed to be thinner, due to the low etch rate of SiNx in KOH, while eliminating the dopant film deposition tool in favor of using the PECVD bARC tool. In one such embodiment, a PECVD SiNₓ layer can be implemented along with other approaches to increase rantex resistance, such as dopant film densification.

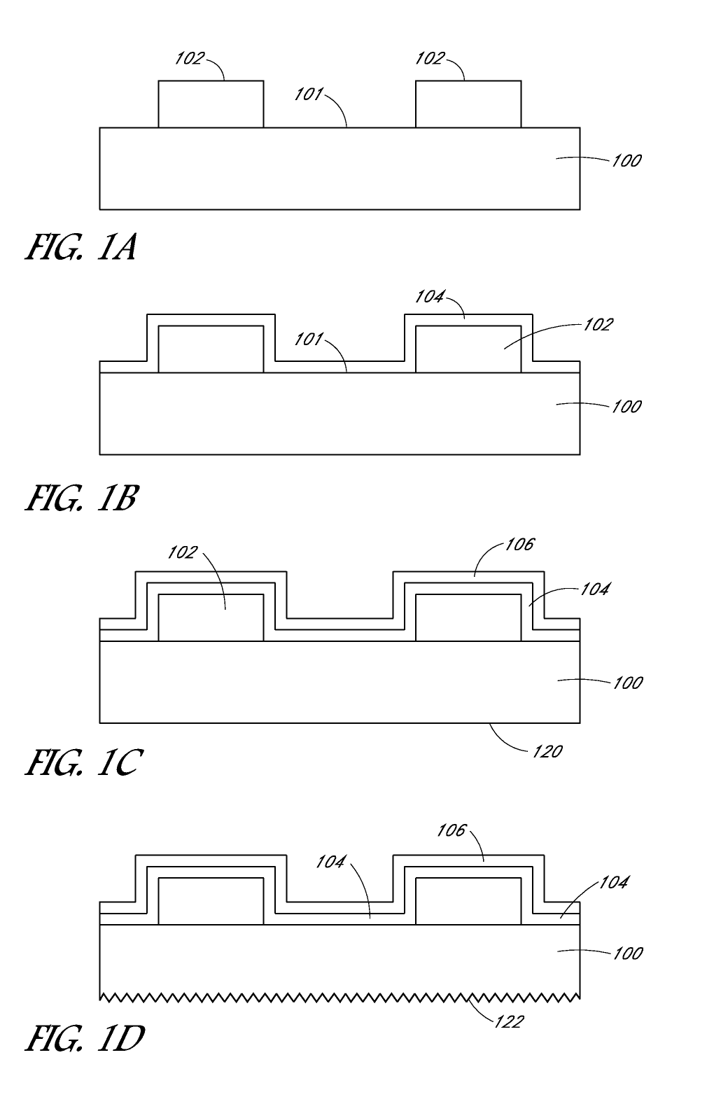

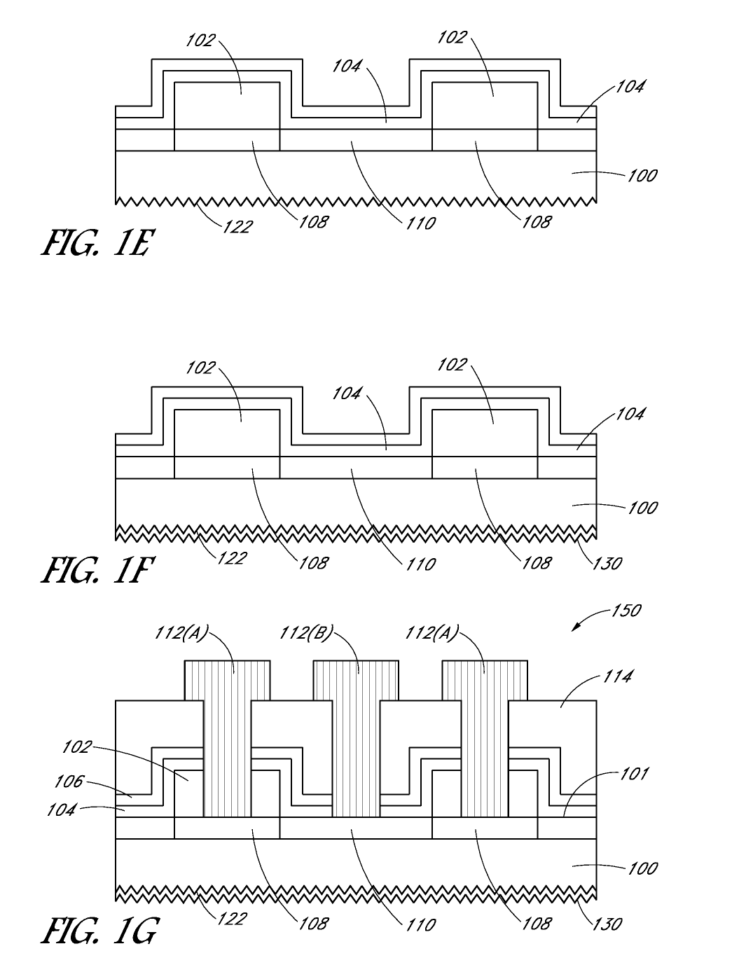

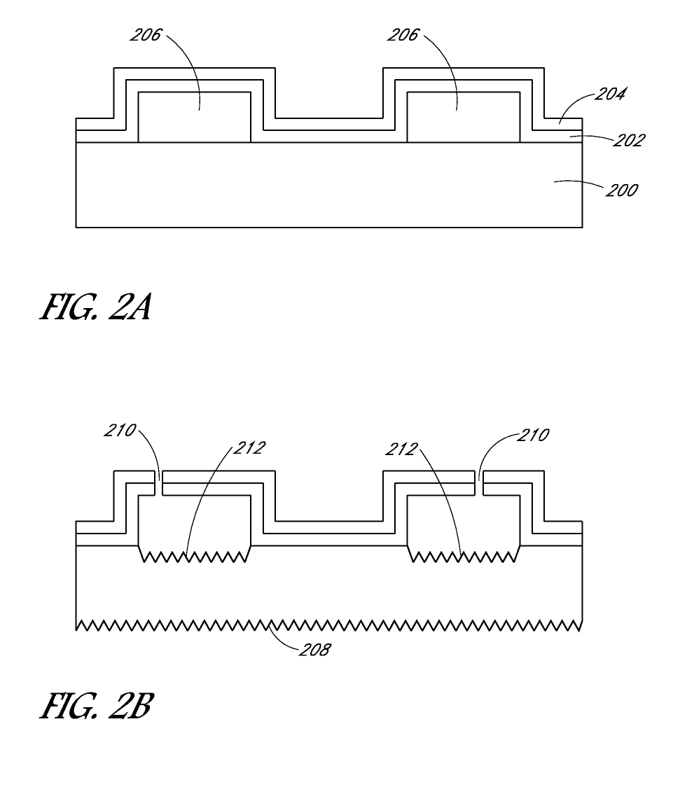

As an example, FIGS. 1A-1G illustrate cross-sectional views of various stages in the fabrication of a solar cell, in accordance with an embodiment of the present invention.

Referring to FIG. 1A, a method of fabricating emitter regions of a solar cell includes forming a plurality of regions of N-type doped silicon nano-particles 102 on a first surface 101 of a substrate 100 of the solar cell. In an embodiment, the substrate 100 is a bulk silicon substrate, such as a bulk single crystalline N-type doped silicon substrate. It is to be understood, however, that substrate 100 may be a layer, such as a polycrystalline silicon layer, disposed on a global solar cell substrate.

In an embodiment, the plurality of regions of N-type doped silicon nano-particles 102 is formed by printing or spin-on coating phosphorous-doped silicon nano-particles on the first surface 101 of a substrate 100. In one such embodiment, the phosphorous-doped silicon nano-particles have an average particles size approximately in the range of 5-100 nanometers and a porosity approximately in the range of 10-50%. In a specific such embodiment, the phosphorous-doped silicon nano-particles are delivered in the presence of a carrier solvent or fluid which can later evaporate or be burned off. In an embodiment, when using a screen print process, it may be preferable to use a liquid source with high viscosity for delivery since using a low viscosity liquid may lead to bleeding, and hence resolution reduction of defined regions.

Referring to FIG. 1B, the method also includes forming a P-type dopant-containing layer 104 on the plurality of regions of N-type doped silicon nano-particles 102 and on the first surface 101 of the substrate 100 between the regions of N-type doped silicon nano-particles 102. In an embodiment, the P-type dopant-containing layer 104 is a layer of borosilicate glass (BSG).

Referring to FIG. 1C, the method also includes forming an etch resistant layer 106 on the P-type dopant-containing layer 104. In an embodiment, the etch resistant layer 106 is a silicon nitride layer. The silicon nitride layer can be of complete stoichiometry (Si₃N₄) or another suitable Si:N stoichiometry, either case represented by SiNₓ.

Referring to FIG. 1D, the method also includes etching a second surface 120 of the substrate 100, opposite the first surface 101, to provide a texturized second surface 122 of the substrate 100. A texturized surface may be one which has a regular or an irregular shaped surface for scattering incoming light, decreasing the amount of light reflected off of the light-receiving surface of the solar cell. In one embodiment, the etching is performed by using a wet etch process such as an alkaline etch based on potassium hydroxide. In an embodiment, the etch resistant layer 106 protects the P-type dopant-containing layer 104 during the etching.

Referring to FIG. 1E, in an embodiment, the method also includes, subsequent to forming the P-type dopant-containing layer 104, heating the substrate 100 to diffuse N-type dopants from the regions of N-type doped silicon nano-particles 102 and form corresponding N-type diffusion regions 108 in the substrate 100. Additionally, P-type dopants are diffused from the P-type dopant-containing layer 104 to form corresponding P-type diffusion regions 110 in the substrate 100, between the N-type diffusion regions 108.

In an embodiment, the heating is performed at a temperature approximately in the range of 850-1100 degrees Celsius for a duration approximately in the range of 1-100 minutes. In one such embodiment, the heating is performed subsequent to the etching used to provide texturized second surface 122 of the substrate 100, as depicted in FIGS. 1D and 1E.

Referring to FIG. 1F, in an embodiment, the method also includes, subsequent to etching the second surface of the substrate 100, forming an anti-reflective coating layer 130 on the texturized second surface 122 of the substrate 100.

Referring to FIG. 1G, in an embodiment, the first surface 101 of the substrate 100 is a back surface of the solar cell, the texturized second surface 122 of the substrate 100 is a light receiving surface of the solar cell, and the method also includes forming metal contacts 112 to the N-type and P-type diffusion regions 108 and 110. In one such embodiment, the contacts 112 are formed in openings of an insulator layer 114 and through remaining portions of the N-type doped silicon nano-particles 102, the P-type dopant-containing layer 104, and the etch resistant layer 106, as depicted in FIG. 1G. In an embodiment, the conductive contacts 112 are composed of metal and are formed by a deposition, lithographic, and etch approach.

Referring again to FIG. 1G, a fabricated solar cell 150 may thus include an emitter region composed of a region of N-type doped silicon nano-particles 102 disposed on a first surface 101 of a substrate 100 of the solar cell 150. A corresponding N-type diffusion region 108 is disposed in the substrate 100. A P-type dopant-containing layer 104 is disposed on the region of N-type doped silicon nano-particles 102 and on the first surface 101 of the substrate 100 adjacent the region of N-type doped silicon nano-particles 102. A corresponding P-type diffusion region 110 is disposed in the substrate 100, adjacent the N-type diffusion region 108. An etch resistant layer 106 is disposed on the P-type dopant-containing layer 104. A first metal contact type 112A is disposed through the etch resistant layer 106, the P-type dopant-containing layer 104 and the region of N-type doped silicon nano-particles 102, and to the N-type diffusion region 108. A second metal contact type 112B is disposed through the etch resistant layer 106 and the P-type dopant-containing layer 104, and to the P-type diffusion region 110.

In an embodiment, the solar cell 150 further includes a texturized second surface 122 of the substrate 100, opposite the first surface 101. In one such embodiment, the first surface 101 of the substrate 100 is a back surface of the solar cell 150, and the second surface 122 of the substrate 100 is a light receiving surface of the solar cell 150. In an embodiment, the solar cell further includes an anti-reflective coating layer 130 disposed on the texturized second surface 122 of the substrate 100. In an embodiment, region of N-type doped silicon nano-particles 102 is composed of phosphorous-doped silicon nano-particles having an average particles size approximately in the range of 5-100 nanometers. In an embodiment, the P-type dopant-containing layer 104 is a layer of borosilicate glass (BSG). In an embodiment, the etch resistant layer 106 is a silicon nitride layer. In an embodiment, the substrate 100 is a single crystalline silicon substrate.

However, in another embodiment, not depicted, remaining portions of the N-type doped silicon nano-particles 102, the P-type dopant-containing layer 104, and the etch resistant layer 106 are removed prior to formation of contacts 112 in openings of the insulator layer 114. In one specific such embodiment, the remaining portions of the N-type doped silicon nano-particles 102, the P-type dopant-containing layer 104, and the etch resistant layer 106 are removed with a dry etch process. In another specific such embodiment, the remaining portions of the N-type doped silicon nano-particles 102, the P-type dopant-containing layer 104, and the etch resistant layer 106 are removed with a wet etch process. In an embodiment, the dry or wet etch process is mechanically aided.

In a second aspect, a silicon nitride (SiNₓ) film is used for rantex resistance for processes involving high etch rates and poorly coated films. As an example of issues with processes not including an etch resistant film, FIGS. 2A and 2B illustrate cross-sectional views of various stages in the fabrication of a solar cell. Referring to FIG. 2A, dopant source film 202 (e.g., borosilicate glass, BSG) deposition followed by cap layer 204 (e.g., undoped silicate glass, USG) deposition is performed over a plurality of regions 206 of n-type silicon nanoparticles disposed above a substrate 200, such as a single crystalline silicon (c-Si) substrate. Referring to FIG. 2B, a front surface 208 texturizing etch, such as a rantex etch, is performed. However, the structure of FIG. 2A can be prone to etch process failure when high etch rate films are introduced into the film stack. For example, while the USG film 204 offers adequate protection from the texture etch under ideal circumstances, the film must be uniform in thickness and free from defects. At either thin points or defects the etchant can penetrate into the structure and etch away the high etch rate film. The rate of thin spots and defects increases with porous films, like particle layers, and other films with poor BSG and USG nucleation due to a non-ideal nucleation surfaces. In dire circumstances, the existence of pin holes 210 leads to etch out of one or more of the regions 206 of n-type silicon nanoparticles and potentially unwanted texturization of the back surface 212 of the substrate 200, as depicted in FIG. 2B.

By contrast, in an embodiment, the addition of a SiNx film to the structure of FIG. 2A prior to the texturizing etch can provide several advantages. For example, the SiNₓ film adds an additional film to the stack, which can be used to cover existing pinhole defects present following the deposition of the BSG and USG films. Another benefit can include the use of SiNₓ with an essentially negligible etch rate in etchants such as KOH, which can be used to texture c-Si substrates. The ultra-low etch rate can ensure that that even thin spots in the SiNx film should be adequate to maintain the integrity of the entire film stack.

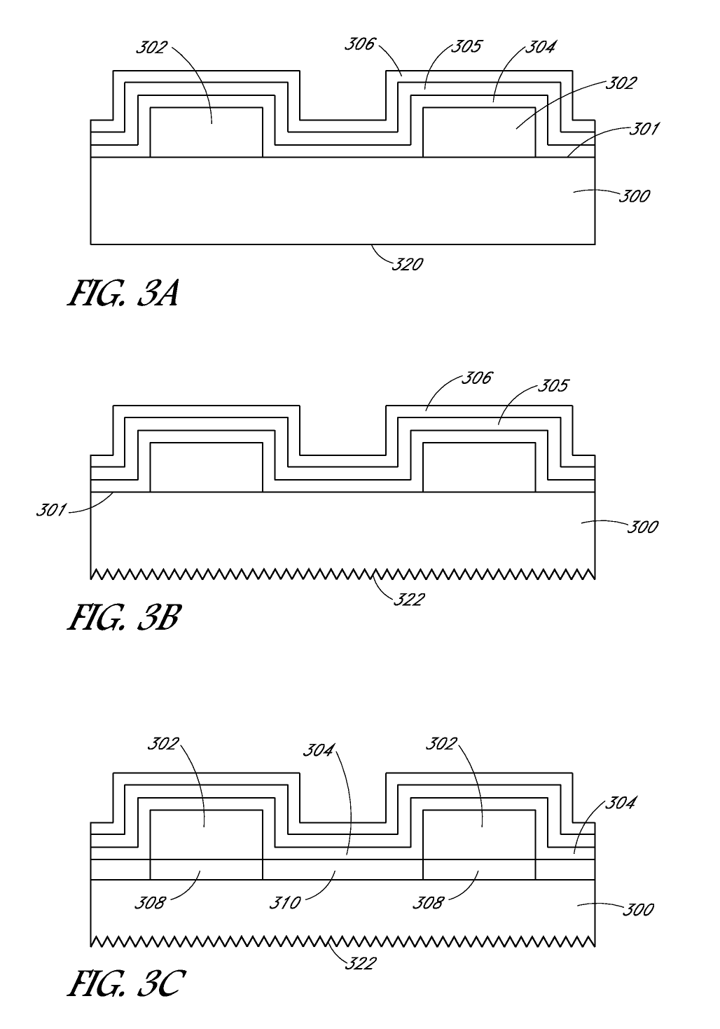

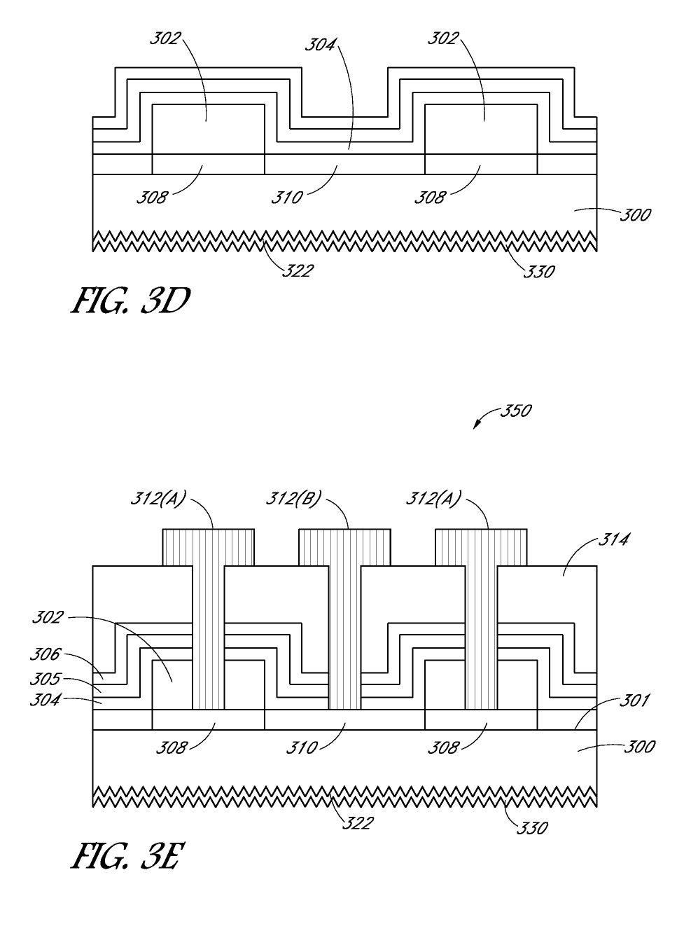

As an example, FIGS. 3A-3E illustrate cross-sectional views of various stages in the fabrication of a solar cell, in accordance with another embodiment of the present invention.

Referring to FIG. 3A, a method of fabricating emitter regions of a solar cell includes forming a plurality of regions of N-type doped silicon nano-particles 302 on a first surface 301 of a substrate 300 of the solar cell. In an embodiment, the substrate 300 is a bulk silicon substrate, such as a bulk single crystalline N-type doped silicon substrate. It is to be understood, however, that substrate 300 may be a layer, such as a polycrystalline silicon layer, disposed on a global solar cell substrate.

In an embodiment, the plurality of regions of N-type doped silicon nano-particles 302 is formed by printing or spin-on coating phosphorous-doped silicon nano-particles on the first surface 301 of a substrate 300. In one such embodiment, the phosphorous-doped silicon nano-particles have an average particles size approximately in the range of 5-100 nanometers and a porosity approximately in the range of 10-50%. In a specific such embodiment, the phosphorous-doped silicon nano-particles are delivered in the presence of a carrier solvent or fluid which can later evaporate or be burned off. In an embodiment, when using a screen print process, it may be preferable to use a liquid source with high viscosity for delivery since using a low viscosity liquid may lead to bleeding, and hence resolution reduction of defined regions.

Referring again to FIG. 3A, the method also includes forming a P-type dopant-containing layer 304 on the plurality of regions of N-type doped silicon nano-particles 302 and on the first surface 301 of the substrate 300 between the regions of N-type doped silicon nano-particles 302. In an embodiment, the P-type dopant-containing layer 304 is a layer of borosilicate glass (BSG).

Referring again to FIG. 3A, the method also includes forming a cap layer 305, such as an undoped silicate glass (USG) layer on the P-type dopant-containing layer 304. An etch resistant layer 306 is then formed on the cap layer 305. In an embodiment, the etch resistant layer 306 is a silicon nitride layer. The silicon nitride layer can be of complete stoichiometry (Si₃N₄) or another suitable Si:N stoichiometry, either case represented by SiNₓ.

Referring to FIG. 3B, the method also includes etching a second surface 320 of the substrate 300, opposite the first surface 301, to provide a texturized second surface 322 of the substrate 300. A texturized surface may be one which has a regular or an irregular shaped surface for scattering incoming light, decreasing the amount of light reflected off of the light-receiving surface of the solar cell. In one embodiment, the etching is performed by using a wet etch process such as an alkaline etch based on potassium hydroxide. In an embodiment, the etch resistant layer 306 protects the cap layer 305, and plugs any pin hole defects therein, during the etching.

Referring to FIG. 3C, in an embodiment, the method also includes, subsequent to forming the P-type dopant-containing layer 304, heating the substrate 300 to diffuse N-type dopants from the regions of N-type doped silicon nano-particles 302 and form corresponding N-type diffusion regions 308 in the substrate 300. Additionally, P-type dopants are diffused from the P-type dopant-containing layer 304 to form corresponding P-type diffusion regions 310 in the substrate 300, between the N-type diffusion regions 308. In an embodiment, the heating is performed at a temperature approximately in the range of 850-1100 degrees Celsius for a duration approximately in the range of 1-100 minutes. In one such embodiment, the heating is performed subsequent to the etching used to provide texturized second surface 322 of the substrate 300, as depicted in FIGS. 3B and 3C.

Referring to FIG. 3D, in an embodiment, the method also includes, subsequent to etching the second surface of the substrate 300, forming an anti-reflective coating layer 330 on the texturized second surface 322 of the substrate 300.

Referring to FIG. 3E, in an embodiment, the first surface 301 of the substrate 300 is a back surface of the solar cell, the texturized second surface 322 of the substrate 300 is a light receiving surface of the solar cell, and the method also includes forming metal contacts 312 to the N-type and P-type diffusion regions 308 and 310. In one such embodiment, the contacts 312 are formed in openings of an insulator layer 314 and through remaining portions of the N-type doped silicon nano-particles 302, the P-type dopant-containing layer 304, the cap layer 305, and the etch resistant layer 306, as depicted in FIG. 3E. In an embodiment, the conductive contacts 312 are composed of metal and are formed by a deposition, lithographic, and etch approach.

Referring again to FIG. 3E, a fabricated solar cell 350 may thus include an emitter region composed of a region of N-type doped silicon nano-particles 302 disposed on a first surface 301 of a substrate 300 of the solar cell 350. A corresponding N-type diffusion region 308 is disposed in the substrate 300. A P-type dopant-containing layer 304 is disposed on the region of N-type doped silicon nano-particles 302 and on the first surface 301 of the substrate 300 adjacent the region of N-type doped silicon nano-particles 302. A corresponding P-type diffusion region 310 is disposed in the substrate 300, adjacent the N-type diffusion region 308. A cap layer 305 is disposed on the P-type dopant-containing layer 304. An etch resistant layer 306 is disposed on the cap layer 305. A first metal contact type 312A is disposed through the etch resistant layer 306, the P-type dopant-containing layer 304 and the region of N-type doped silicon nano-particles 302, and to the N-type diffusion region 308. A second metal contact type 312B is disposed through the etch resistant layer 306 and the P-type dopant-containing layer 304, and to the P-type diffusion region 310.

In an embodiment, the solar cell 350 further includes a texturized second surface 322 of the substrate 300, opposite the first surface 301. In one such embodiment, the first surface 301 of the substrate 300 is a back surface of the solar cell 350, and the second surface 322 of the substrate 300 is a light receiving surface of the solar cell 350. In an embodiment, the solar cell further includes an anti-reflective coating layer 330 disposed on the texturized second surface 322 of the substrate 300. In an embodiment, region of N-type doped silicon nano-particles 302 is composed of phosphorous-doped silicon nano-particles having an average particles size approximately in the range of 5-100 nanometers. In an embodiment, the P-type dopant-containing layer 304 is a layer of borosilicate glass (BSG), while the cap layer 305 is a layer of undoped silicate glass (USG). In an embodiment, the etch resistant layer 306 is a silicon nitride layer. In an embodiment, the substrate 300 is a single crystalline silicon substrate.

More generally, referring again to FIGS. 1G and 3E, a porous layer silicon nano-particle layer may be retained on a substrate of a solar cell. Therefore, a solar cell structure may ultimately retain, or at least temporarily include, such a porous layer as a consequence of processing operations. In an embodiment, portions of a porous silicon nano-particle layer (e.g., 102 or 302) are not removed in process operations used to fabricate the solar cell, but rather remain as an artifact on the surface of a substrate, or on a layer or stack of layers above a global substrate, of the solar cell.

However, in another embodiment, not depicted, remaining portions of the N-type doped silicon nano-particles 302, the P-type dopant-containing layer 304, the cap layer 305, and the etch resistant layer 306 are removed prior to formation of contacts 312 in openings of the insulator layer 314. In one specific such embodiment, the remaining portions of the N-type doped silicon nano-particles 302, the P-type dopant-containing layer 304, the cap layer 305, and the etch resistant layer 306 are removed with a dry etch process. In another specific such embodiment, the remaining portions of the N-type doped silicon nano-particles 302, the P-type dopant-containing layer 304, the cap layer 305, and the etch resistant layer 306 are removed with a wet etch process. In an embodiment, the dry or wet etch process is mechanically aided.

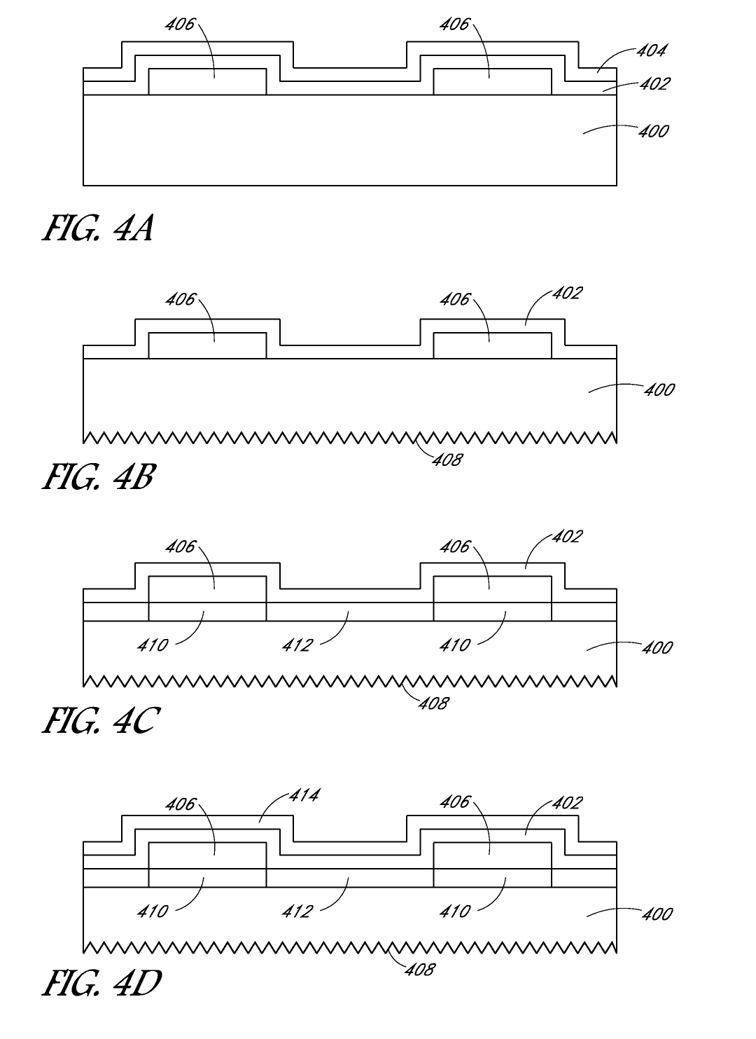

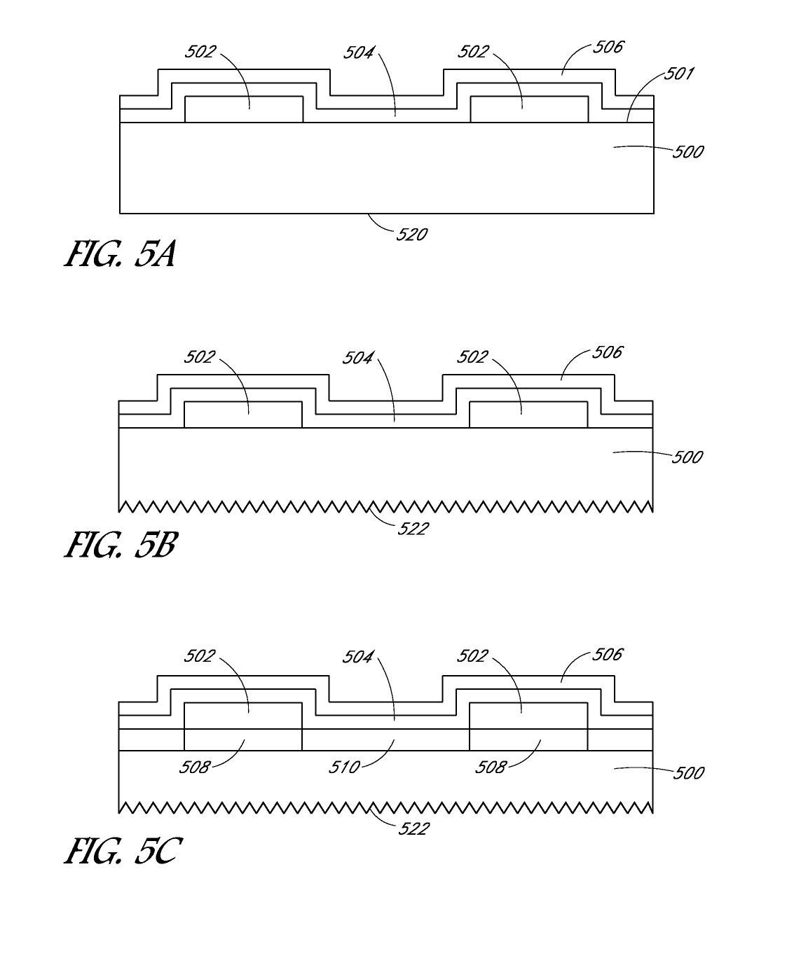

In a third aspect, a silicon nitride (SiNₓ) film is used for rantex resistance and provides processes with reduced cost and reduced operation number. As an example of issues with processes not including an etch resistant film, FIGS. 4A-4D illustrate cross-sectional views of various stages in the fabrication of a solar cell. Referring to FIG. 4A, P-type dopant source film 402 (e.g., borosilicate glass, BSG) deposition followed by cap layer 404 (e.g., undoped silicate glass, USG) is performed over a plurality of regions 406 of an N-type dopant source film (e.g., phosphosilicate glass, PSG) disposed above a substrate 400, such as a single crystalline silicon (c-Si) substrate. Referring to FIG. 4B, a front surface 408 texturizing etch, such as a rantex etch, is performed. The cap layer 404 may be removed during the etch process, as depicted in FIG. 4B. Diffusion from the dopant layers is then performed to provide doped regions 410 and 412, respectively. Finally, an anti-reflective coating layer 414, such as a SiNₓ film, is formed on the structure of FIG. 4C, as depicted in FIG. 4D.

By contrast, in an embodiment, the deposition of the SiNₓ layer is performed prior to the texture etch to enable reduction or removal of the USG film, resulting in a cost savings by eliminating the material and process required for the USG deposition. In the current structure, most or all of the USG film is consumed during the front surface texture etch anyway. Operations could also be reduced by combining the second dopant film deposition (described as BSG, but could be PSG instead to invert the dopant flows) with the SiNₓ deposition. The PSG, BSG and USG layers can be deposited by CVD, or the outer layer can be, in another embodiment, deposited by PECVD followed by either USG+SiNₓ deposition or SiNₓ deposition in a single tool.

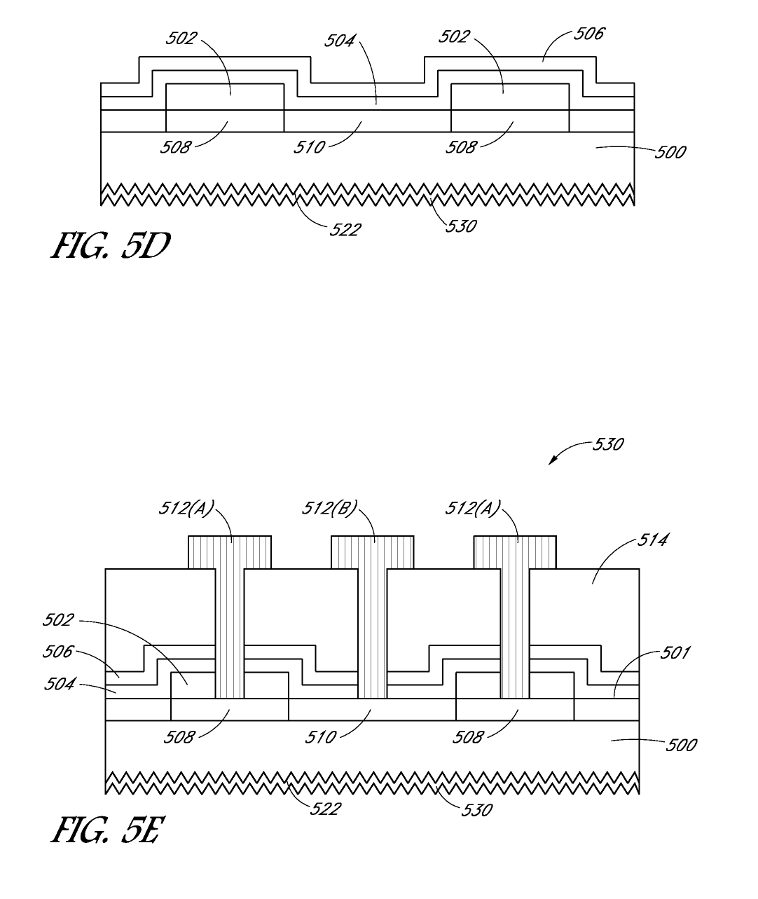

As an example, FIGS. 5A-5E illustrate cross-sectional views of various stages in the fabrication of a solar cell, in accordance with another embodiment of the present invention.

Referring to FIG. 5A, a method of fabricating emitter regions of a solar cell includes forming a plurality of regions 502 of an N-type dopant source film (e.g., phosphosilicate glass, PSG) on a first surface 501 of a substrate 500 of the solar cell. In an embodiment, the substrate 500 is a bulk silicon substrate, such as a bulk single crystalline N-type doped silicon substrate. It is to be understood, however, that substrate 500 may be a layer, such as a polycrystalline silicon layer, disposed on a global solar cell substrate.

Referring again to FIG. 5A, the method also includes forming a P-type dopant-containing layer 504 on the plurality of regions 502 of the N-type dopant source film and on the first surface 501 of the substrate 500 between the regions of the N-type dopant source film 502. In an embodiment, the P-type dopant-containing layer 504 is a layer of borosilicate glass (BSG).

Referring again to FIG. 5A, the method also includes forming an etch resistant layer 506 on the P-type dopant-containing layer 504. In an embodiment, the etch resistant layer 506 is a silicon nitride layer. The silicon nitride layer can be of complete stoichiometry (Si₃N₄) or another suitable Si:N stoichiometry, either case represented by SiNₓ.

Referring to FIG. 5B, the method also includes etching a second surface 520 of the substrate 500, opposite the first surface 501, to provide a texturized second surface 522 of the substrate 500. A texturized surface may be one which has a regular or an irregular shaped surface for scattering incoming light, decreasing the amount of light reflected off of the light-receiving surface of the solar cell. In one embodiment, the etching is performed by using a wet etch process such as an alkaline etch based on potassium hydroxide. In an embodiment, the etch resistant layer 506 protects the P-type dopant-containing layer 504 during the etching.

Referring to FIG. 5C, in an embodiment, the method also includes, subsequent to forming the P-type dopant-containing layer 504, heating the substrate 500 to diffuse N-type dopants from the regions 502 of the N-type dopant source film and form corresponding N-type diffusion regions 508 in the substrate 500. Additionally, P-type dopants are diffused from the P-type dopant-containing layer 504 to form corresponding P-type diffusion regions 510 in the substrate 500, between the N-type diffusion regions 508.

In an embodiment, the heating is performed at a temperature approximately in the range of 850-1100 degrees Celsius for a duration approximately in the range of 1-100 minutes. In one such embodiment, the heating is performed subsequent to the etching used to provide texturized second surface 522 of the substrate 500, as depicted in FIGS. 5B and 5C.

Referring to FIG. 5D, in an embodiment, the method also includes, subsequent to etching the second surface of the substrate 500, forming an anti-reflective coating layer 530 on the texturized second surface 522 of the substrate 500.

Referring to FIG. 5E, in an embodiment, the first surface 501 of the substrate 500 is a back surface of the solar cell, the texturized second surface 522 of the substrate 500 is a light receiving surface of the solar cell, and the method also includes forming metal contacts 512 to the N-type and P-type diffusion regions 508 and 510. In one such embodiment, the contacts 512 are formed in openings of an insulator layer 514 and through remaining portions of regions 502 of the N-type dopant source film, the P-type dopant-containing layer 504, and the etch resistant layer 506, as depicted in FIG. 5E. In an embodiment, the conductive contacts 512 are composed of metal and are formed by a deposition, lithographic, and etch approach.

Referring again to FIG. 5E, a fabricated solar cell 550 may thus include an emitter region composed of regions 502 of an N-type dopant source film disposed on a first surface 501 of a substrate 500 of the solar cell 550. A corresponding N-type diffusion region 508 is disposed in the substrate 500. A P-type dopant-containing layer 504 is disposed on the regions 502 of the N-type dopant source film and on the first surface 501 of the substrate 500 adjacent regions 502 of the N-type dopant source film. A corresponding P-type diffusion region 510 is disposed in the substrate 500, adjacent the N-type diffusion region 508. An etch resistant layer 506 is disposed on the P-type dopant-containing layer 504. A first metal contact type 512A is disposed through the etch resistant layer 506, the P-type dopant-containing layer 504 and the regions 502 of the N-type dopant source film, and to the N-type diffusion region 508. A second metal contact type 512B is disposed through the etch resistant layer 506 and the P-type dopant-containing layer 504, and to the P-type diffusion region 510.

In an embodiment, the solar cell 550 further includes a texturized second surface 522 of the substrate 500, opposite the first surface 501. In one such embodiment, the first surface 501 of the substrate 500 is a back surface of the solar cell 550, and the second surface 522 of the substrate 500 is a light receiving surface of the solar cell 550. In an embodiment, the solar cell further includes an anti-reflective coating layer 530 disposed on the texturized second surface 522 of the substrate 500. In an embodiment, regions 502 of an N-type dopant source film are composed of a phosphoslicate glass (PSG) layer. In an embodiment, the P-type dopant-containing layer 504 is a layer of borosilicate glass (BSG). In an embodiment, the etch resistant layer 506 is a silicon nitride layer. In an embodiment, the substrate 500 is a single crystalline silicon substrate.

However, in another embodiment, not depicted, remaining portions of the regions 502 of the N-type dopant source film, the P-type dopant-containing layer 504, and the etch resistant layer 506 are removed prior to formation of contacts 512 in openings of the insulator layer 514. In one specific such embodiment, the remaining portions of the regions 502 of the N-type dopant source film, the P-type dopant-containing layer 504, and the etch resistant layer 506 are removed with a dry etch process. In another specific such embodiment, the remaining portions of the regions 502 of the N-type dopant source film, the P-type dopant-containing layer 504, and the etch resistant layer 506 are removed with a wet etch process. In an embodiment, the dry or wet etch process is mechanically aided.

Overall, although certain materials are described specifically above, some materials may be readily substituted with others with other such embodiments remaining within the spirit and scope of embodiments of the present invention. For example, in an embodiment, a different material substrate, such as a group III-V material substrate, can be used instead of a silicon substrate. Furthermore, it is to be understood that, where N+ and P+ type doping is described specifically, other embodiments contemplated include the opposite conductivity type, e.g., P+ and N+ type doping, respectively. In other embodiments, the doped silicon nano-particles may more generally be described as a printable dopant, where equivalents may be used in place of the specifically described doped silicon nano-particles. Other printable dopants may include oxide-based (particle or siloxane) printable dopant formulations and/or can be porous, and/or have high etch rates, both of which render increased etch protection relevant.

Thus, methods of fabricating solar cell emitter regions using etch resistant films and the resulting solar cells have been disclosed. In accordance with an embodiment of the present invention, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. A capping layer is formed on the P-type dopant-containing layer. An etch resistant layer is formed on the capping layer. A second surface of the substrate, opposite the first surface, is etched to texturize the second surface of the substrate. The etch resistant layer protects the capping layer and the P-type dopant-containing layer during the etching. In one embodiment, the substrate is a single crystalline silicon substrate, and etching the second surface of the substrate involves treating the second surface with a hydroxide-based wet etchant.

1. A method of fabricating an emitter region of a solar cell, the method comprising:
forming a plurality of regions of N-type doped silicon nano-particles on a first surface of a substrate of the solar cell;
forming a P-type dopant-containing layer on the plurality of regions of N-type doped silicon nano-particles and on the first surface of the substrate between the regions of N-type doped silicon nano-particles;
forming a capping layer on the P-type dopant-containing layer;
forming an etch resistant layer on the capping layer; and
etching a second surface of the substrate, opposite the first surface, to texturize the second surface of the substrate, wherein the etch resistant layer protects the capping layer and the P-type dopant-containing layer during the etching.

2. The method of claim 1, further comprising:
subsequent to forming the P-type dopant-containing layer, heating the substrate to diffuse N-type dopants from the regions of N-type doped silicon nano-particles and form corresponding N-type diffusion regions in the substrate, and to diffuse P-type dopants from the P-type dopant-containing layer and form corresponding P-type diffusion regions in the substrate, between the N-type diffusion regions.

3. The method of claim 2, wherein the heating is performed at a temperature approximately in the range of 850-1100 degrees Celsius for a duration approximately in the range of 1-100 minutes.

4. The method of claim 2, wherein the heating is performed subsequent to the etching.

5. The method of claim 2, wherein the first surface of the substrate is a back surface of the solar cell, the second surface of the substrate is a light receiving surface of the solar cell, the method further comprising:
forming metal contacts to the N-type and P-type diffusion regions.

6. The method of claim 1, further comprising:
subsequent to etching the second surface of the substrate, forming an anti-reflective coating layer on the texturized second surface of the substrate.

7. The method of claim 1, wherein forming the plurality of regions of N-type doped silicon nano-particles comprises printing or spin-on coating phosphorous-doped silicon nano-particles having an average particles size approximately in the range of 5-100 nanometers and a porosity approximately in the range of 10-50%.

8. The method of claim 1, wherein forming the P-type dopant-containing layer comprises forming a layer of borosilicate glass (BSG).

9. The method of claim 1, wherein forming the etch resistant layer comprises forming a silicon nitride layer.

10. The method of claim 1, wherein forming the capping layer comprises forming a layer of undoped silicate glass (USG).

11. The method of claim 1, wherein the substrate is a single crystalline silicon substrate, and wherein etching the second surface of the substrate comprises treating the second surface with a hydroxide-based wet etchant.

12. A solar cell fabricated according to the method of claim 1.

13. A method of fabricating an emitter region of a solar cell, the method comprising:
forming a plurality of regions of an N-type dopant source film on a first surface of a substrate of the solar cell;
forming a P-type dopant-containing layer on the plurality of regions of the N-type dopant source film and on the first surface of the substrate between the regions of the N-type dopant source film;
forming an etch resistant layer on the P-type dopant-containing layer; and
etching a second surface of the substrate, opposite the first surface, to texturize the second surface of the substrate, wherein the etch resistant layer protects the P-type dopant-containing layer during the etching.

14. The method of claim 13, further comprising:
subsequent to forming the P-type dopant-containing layer, heating the substrate to diffuse N-type dopants from the regions of the N-type dopant source film and form corresponding N-type diffusion regions in the substrate, and to diffuse P-type dopants from the P-type dopant-containing layer and form corresponding P-type diffusion regions in the substrate, between the N-type diffusion regions.

15. The method of claim 14, wherein the heating is performed at a temperature approximately in the range of 850-1100 degrees Celsius for a duration approximately in the range of 1-100 minutes, and wherein the heating is performed subsequent to the etching.

16. The method of claim 14, wherein the first surface of the substrate is a back surface of the solar cell, the second surface of the substrate is a light receiving surface of the solar cell, the method further comprising:
forming metal contacts to the N-type and P-type diffusion regions.

17. The method of claim 13, further comprising:
subsequent to etching the second surface of the substrate, forming an anti-reflective coating layer on the texturized second surface of the substrate.

18. The method of claim 13, wherein forming the plurality of regions of the N-type dopant source film comprises forming a layer of phosphosilicate glass (PSG), wherein forming the P-type dopant-containing layer comprises forming a layer of borosilicate glass (BSG) and wherein forming the etch resistant layer comprises forming a silicon nitride layer.

19. The method of claim 13, wherein the substrate is a single crystalline silicon substrate, and wherein etching the second surface of the substrate comprises treating the second surface with a hydroxide-based wet etchant.

20. A solar cell fabricated according to the method of claim 13.

21.-29. (canceled)
